(19) United States
(12) Patent Application Publication
(10) Pub. No.: US 2011/0272667 A1
(43) Pub. Date: Nov. 10, 2011

(54) SEMICONDUCTOR LIGHT EMITTING DEVICE

(76) Inventor: Toru TAKAYAMA, Hyogo (JP)

(21) Appl. No.: 13/094,013

(22) Filed: Apr. 26, 2011

(30) Foreign Application Priority Data
May 7, 2010 (JP) 2010-107181

(51) Int. Cl. H01L 33/06

(52) U.S. Cl. 257/13; 257/E33.008

(57) ABSTRACT

A semiconductor light emitting device includes: a first cladding layer made of a first conductivity type group III nitride semiconductor; an active layer formed on the first cladding layer; a quantum well electron barrier layer which is formed on the active layer, and includes electron trapping barrier layers made of Al_{xb}Ga_{yb}In_{1-xb-yb}N (0≦xb<1, 0<yb≦1, 0≦1-xb-yb<1), and two or more electron trapping well layers made of Al_{xw}Ga_{yw}In_{1-xw-yw}N (0≦xw<1, 0<yw≦1, 0≦1-xw-yw<1); and a second cladding layer which is formed on the quantum well electron barrier layer, and is made of a second conductive type group III nitride semiconductor. Each of the electron trapping well layers is formed between the electron trapping barrier layers, and band gap energies of the electron trapping well layers increase with decreasing distance from the active layer.

### CROSS-REFERENCE TO RELATED APPLICATION

This application claims priority to Japanese Patent Application No. 2010-107181 filed on May 7, 2010, the disclosure of which including the specification, the drawings, and the claims is hereby incorporated by reference in its entirety.

### BACKGROUND

The present disclosure relates to semiconductor light emitting devices, particularly to high-power semiconductor light emitting devices.

Due to increase in capacity of optical disc systems in recent years, Blu-ray (registered trademark) optical disc systems having larger storage capacity than compact discs (CD) and digital versatile discs (DVD) have appeared on the market. Semiconductor laser devices which use a nitride compound, and are capable of producing blue-violet laser light having a wavelength of 405 nm (hereinafter referred to as semiconductor lasers) have been and are being practically used.

The semiconductor lasers used as light sources of the optical disc systems are required to be able to provide high power output (high power operation), and to operate stably at a high temperature of 85° C. or higher (high temperature operation) to keep up with the increase in recording speed.

The high power and high temperature operation of the semiconductor lasers may be inhibited by, for example, increase in operating current due to leakage of current in the high temperature operation. The operating current increases when electrons which are injected in an active layer of the semiconductor laser are excited by self heating of the semiconductor layer, and leak to a p-type cladding layer (overflow). The increase in operating current leads to further self heating of the semiconductor laser, thereby reducing reliability of long-term operation of the semiconductor laser.

Another possible cause which inhibits the high power and high temperature operation is increase in operating voltage. When the operating voltage increases, power for operating the semiconductor laser increases, thereby raising temperature due to Joule heat. As a result, the operating current further increases, and the operating voltage further increases, thereby significantly reducing the reliability of the semiconductor laser. The highest voltage for operating a drive circuit for driving the semiconductor laser is limited. Therefore, the increase in operating voltage is a significant problem, and has to be resolved to ensure reliability, and to control the operation by the drive circuit with reliability.

To prevent the overflow of the electrons from the active layer in the semiconductor laser, in general, a p-type semiconductor layer having a larger band gap energy than that of the active layer is provided near the active layer to form a potential barrier (ΔEc) in a conduction band. In a blue-violet nitride semiconductor laser, the active layer is generally a multiple quantum well (MQW) layer made of an indium gallium nitride (InGaN)-based material, and a cladding layer is generally made of an aluminum gallium nitride (AlGaN)-based material. In this case, when the composition of aluminum (Al) in the cladding layer is increased to increase ΔEc for the purpose of reducing the overflow of the electrons, cracks are generated in the semiconductor laser due to difference in thermal expansion coefficient between the AlGaN-based material and the InGaN-based material.

Japanese Patent Publications Nos. 2000-183462 and 2001-223441, etc. teach semiconductor light emitting devices which address the above problems.

A first conventional example of the semiconductor light emitting device will be described with reference to FIGS. 12 and 13.

As shown in FIG. 12, an n-type contact layer 202 made of AlₐGa₁₋ₐN (0<a<1) doped with n-type impurities such as silicon (Si) etc., an anti-crack layer 203 made of Si-doped In_{g}Ga_{1-g}N (0.05≦g≦0.2), and an n-type cladding layer 204 which is a layered film containing AlₑGa₁₋ₑN (0.12≦e<0.15), are sequentially formed on a nitride semiconductor substrate 201. An n-type guiding layer 205 made of undoped gallium nitride (GaN), a multiple quantum well active layer 206 made of In_{b}Ga_{1-b}N (0≦b<1), and at least one p-type electron trapping layer 207 made of magnesium (Mg)-doped Al_{d}Ga_{1-d}N (0<d≦1) are sequentially formed on the n-type cladding layer 204. A p-type guiding layer 208 made of undoped GaN, and a p-type cladding layer 209 which is a layered film containing Al_{f}Ga_{1-f}N (0<f≦1), and has a ridge are sequentially formed on the p-type electron trapping layer 207. A p-type contact layer 210 made of Mg-doped GaN is formed on a top surface of the ridge of the p-type cladding layer 209, and a protective film 213 is formed on a surface of the p-type cladding layer 209 except for the top surface of the ridge. A p-side electrode 211 is formed on the p-type contact layer 210 and the protective film 213, and an n-side electrode 212 is formed on the n-type contact layer 202 where the anti-crack layer 203 is not formed.

In this structure, electrons injected from the n-side electrode 212 are injected in the active layer 206 through the n-type cladding layer 204. The electrons in the active layer are excited by heat in the high power and high temperature operation. As shown in FIG. 13, overflow of the electrons is reduced by a potential barrier ΔEc at an interface between the p-type electron trapping layer 207 and the active layer 206.

The p-type electron trapping layer 207 is thinned to 1 nm-100 nm, thereby reducing cracking of the semiconductor light emitting device.

A second conventional example of the semiconductor light emitting device will be described with reference to FIGS. 14 and 15.

As shown in FIG. 14, a MQW active layer 307 is formed by alternately stacking a plurality of GaN compound semiconductor layers 302 and 303 on an n-type GaN layer 301. At least two or more sets of a AlₓGa₁₋ₓN layer (a barrier layer) 304 and a GaN layer (a well layer) 305 are stacked on the active layer 307 to form a p-type multiple quantum barrier (MQB) layer 308 having a multiple quantum barrier structure including multiple energy levels. A p-type GaN layer 306 is formed on the p-type MQB layer 308.

In this structure, electrons injected from the n-type GaN layer 301 are injected in the active layer 307. The electrons in the active layer 307 are excited by heat in the high power and high temperature operation, but the overflow of the electrons is reduced by a potential barrier ΔEc at an interface between the p-type MQB layer 308 and the active layer 307. As shown in FIG. 15, the well layers 305 constituting the p-type MQB layer 308 have the same band gap energy, and their thicknesses decrease with decreasing distance from the active layer 307. With the p-type MQB layer 308 including these well layers stacked on the active layer 307, the cracking can be reduced, and ΔEc, which is more effective than that of the first conventional example, can relatively be increased by quantum effect.

This can provide a semiconductor light emitting device which can reduce the overflow of the electrons even in the high power and high temperature operation, and can be driven at a low operating current.

### SUMMARY

The AlGaN layer formed on the active layer can reduce the overflow of the electrons, but forms a potential barrier (ΔEv) in a valence band to holes injected from the p-side electrode to the active layer. Thus, the AlGaN layer functions as an energy barrier.

In the first and second conventional examples, the overflow of the electrons can be reduced. However, the operating voltage is increased because the energy barrier to the holes is formed.

When the holes travel through the MQB layer toward the active layer in the conventional MQB structure, the holes can tunnel through the barrier layers by quantum tunneling, but they are more likely to be at ground levels in the well layers where energy is the lowest. The holes may tunnel through the barrier layers constituting the MQB layer by quantum tunneling, or by obtaining energy higher than potential energies of the barrier layers. Therefore, when the holes pass through the barrier layers constituting the MQB layer by obtaining the potential energy higher than those of the barrier layers, a bias voltage corresponding to a difference between the ground levels of the well layers and the potential energies of the barrier layers in the MQB layer has to be applied. This increases the operating voltage.

In the blue-violet nitride semiconductor laser, the increase in operating voltage leads to increase in operating temperature and operating current of the semiconductor laser, thereby reducing reliability, and ranges of temperature and laser output in which stable operation is allowed.

In view of the foregoing, the present disclosure has been achieved to provide a semiconductor light emitting device which allows high power operation at a low operating current and a low operating voltage.

The disclosed semiconductor light emitting device includes an electron barrier layer which includes a stack of layers having different band gap energies.

Specifically, the disclosed semiconductor light emitting device includes: a first cladding layer made of a first conductivity type group III nitride semiconductor; an active layer formed on the first cladding layer; a quantum well electron barrier layer which is formed on the active layer, and includes electron trapping barrier layers made of Al_{xb}Ga_{yb}In_{1-xb-yb}N (0≦xb<1, 0<yb≦1, 0≦1-xb-yb<1), and two or more electron trapping well layers made of Al_{xw}Ga_{yw}In_{1-xw-yw}N (0≦xw<1, 0<yw≦1, 0≦1-xw-yw<1); and a second cladding layer which is formed on the quantum well electron barrier layer, and is made of a second conductive type group III nitride semiconductor, wherein each of the electron trapping well layers is formed between the electron trapping barrier layers, and band gap energies of the electron trapping well layers increase with decreasing distance from the active layer.

In the disclosed semiconductor light emitting device, the number of energy levels in the electron trapping well layers decreases, and the magnitude of the highest energy level gradually increases, with decreasing distance from the active layer. Thus, the injected holes can selectively be at the energy levels increased with decreasing distance from the active layer. Even when the applied bias voltage is low, the holes are more likely to pass through a potential barrier (ΔEv) in a valence band between the second cladding layer and the quantum well electron barrier layer. This can efficiently reduce the operating voltage.

Since the band gap energies of the electron trapping well layers in the quantum well electron barrier layer increase with decreasing distance from the active layer, the number of energy levels in the electron trapping well layers decreases, and the magnitude of the highest energy level gradually increases, with decreasing distance from the active layer. Therefore, the overflow of the electrons injected in the active layer can be reduced even when the electron trapping barrier layer closest to the active layer is as extremely thin as about 10 nm or less.

In the disclosed semiconductor light emitting device, xw representing a composition ratio of Al in the electron trapping well layer closest to the second cladding layer is preferably 0 to 0.05, both inclusive.

With this configuration, the number of energy levels in the electron trapping well layer closest to the second cladding layer increases, and the holes are more likely to pass through the electron trapping barrier layers from the second cladding layer to reach the electron trapping well layer closest to the second cladding layer. Thus, the holes can flow to the active layer even when the applied bias voltage is low.

In the disclosed semiconductor light emitting device, thicknesses of the electron trapping well layers are preferably 2 nm to 6 nm, both inclusive, and thicknesses of the electron trapping barrier layers are preferably 2 nm to 8 nm, both inclusive.

With this configuration, quantum levels can be formed in the electron trapping well layers with good controllability, and carriers are more likely to tunnel through the electron trapping barrier layers by quantum tunneling.

In the disclosed semiconductor light emitting device, thicknesses of the electron trapping well layers preferably decrease with decreasing distance from the active layer.

With this configuration, the magnitude of electron energy levels formed in the electron trapping well layers increase with decreasing distance from the active layer. Thus, the electrons injected in the active layer are less likely to tunnel through the electron trapping barrier layer closest to the active layer by quantum tunneling. This can reduce the overflow of the electrons from the active layer, and the semiconductor light emitting device can be operated at a low operating current with reduced leak current even in the high power and high temperature operation.

In the disclosed semiconductor light emitting device, the first cladding layer is preferably formed on a semiconductor substrate.

When the semiconductor substrate is provided with conductivity, the semiconductor light emitting device can be driven by an electrode formed on a surface of the semiconductor light emitting device, and an electrode formed on a rear surface of the semiconductor substrate. Therefore, it is no longer necessary to form n-side and p-side electrodes on the same surface of the semiconductor substrate, thereby downsizing the semiconductor light emitting device.

In this case, the semiconductor substrate is preferably made of gallium nitride.

With this configuration, the semiconductor substrate is made of a material similar to the nitride material constituting the semiconductor light emitting device. Thus, as compared with the case where the substrate is made of other materials such as silicon, gallium arsenide, etc., a lattice constant and a thermal expansion coefficient of the substrate can be closer to those of the layers constituting the semiconductor light emitting device. Gallium nitride has good thermal conductivity, and can improve heat dissipation. This can improve reliability of the semiconductor light emitting device in long-term operation.

In the disclosed semiconductor light emitting device, xb representing a composition of Al in the electron trapping barrier layer closest to the active layer is preferably 0.2 or higher.

With this configuration, a high energy barrier can be formed in the conduction band, thereby reducing the overflow of the electrons. Thus, the semiconductor light emitting device can be operated at a low operating current with reduced leak current even in the high power and high temperature operation.

In the disclosed semiconductor light emitting device, a lattice constant of each of the electron trapping barrier layers is preferably smaller than a lattice constant of the semiconductor substrate.

With this configuration, the electron trapping barrier layers experience tensile strain, and the band gap energies of the electron trapping barrier layers increase. This can increase energies of quantum levels formed in the electron trapping well layers, thereby further increasing the electron energy levels formed in the electron trapping well layer closest to the active layer. As a result, the electrons injected in the active layer are less likely to tunnel through the electron trapping barrier layer closest to the active layer by quantum tunneling. This can reduce the overflow of the electrons from the active layer, and the semiconductor light emitting device can be operated at a low operating current with reduced leak current even in the high power and high temperature operation.

In the disclosed semiconductor light emitting device, 2-0.01≦(Lb+Lw)/Lg≦2+0.01 is preferably satisfied, where Lb is a lattice constant of the electron trapping barrier layer, Lw is a lattice constant of the electron trapping well layer, and Lg is a lattice constant of gallium nitride.

With this configuration, lattice mismatch occurs in the electron trapping well layers in a direction opposite to lattice mismatch of the electron trapping barrier layers, and strain of the electron trapping barrier layers can be canceled by strain of the electron trapping well layers. Thus, even when the Al composition ratio in the electron trapping barrier layers is increased to 0.2 or higher, lattice defects due to the difference in thermal expansion coefficient between the active layer and the electron trapping barrier layers are less likely to occur. This configuration can reduce the occurrence of lattice defects due to lattice mismatch between gallium nitride constituting the semiconductor substrate, and the electron trapping barrier layers and the electron trapping well layers.

Thus, the disclosed semiconductor light emitting device can be driven at a low operation voltage and a low operation current even in the high power and high temperature operation.

### BRIEF DESCRIPTION OF THE DRAWINGS

FIG. 1 is a cross-sectional view illustrating the structure of semiconductor light emitting devices of first to fourth example embodiments.

FIG. 2 is a cross-sectional view illustrating details of a quantum well electron barrier layer of the semiconductor light emitting device of the first example embodiment.

FIG. 3 shows a band structure near an active layer and the quantum well electron barrier layer of the semiconductor light emitting device of the first example embodiment.

FIG. 4 shows a band structure indicating relationship between a difference between conduction band edge energy of an electron trapping barrier layer and an electron energy level (ΔEcq), and a difference between valence band edge energy of an electron trapping barrier layer and a hole energy level (ΔEvq) of the semiconductor light emitting device of the first example embodiment.

FIG. 5A shows a graph illustrating relationship between Al composition ratio in a 4 nm thick electron trapping well layer and calculated ΔEcq of an electron trapping well layer in the semiconductor light emitting device of the first and second example embodiments. FIG. 5B shows a graph illustrating relationship between the Al composition ratio in the 4 nm thick electron trapping well layer and calculated ΔEvq of the electron trapping well layer of the first and second example embodiments.

FIG. 6A shows a graph illustrating relationship between Al composition ratio in a 2 nm thick electron trapping well layer and calculated ΔEcq of an electron trapping well layer of the semiconductor light emitting device of the second example embodiment. FIG. 6B shows a graph illustrating relationship between the Al composition ratio in the 2 nm thick electron trapping well layer and calculated ΔEvq of the electron trapping well layer of the semiconductor light emitting device of the second example embodiment.

FIG. 7A is a graph illustrating relationship between Al composition ratio in a 6 nm thick electron trapping well layer and calculated ΔEcq of an electron trapping well layer of the semiconductor light emitting device of the second example embodiment. FIG. 7B is a graph illustrating relationship between the Al composition ratio in the 6 nm thick electron trapping well layer and calculated ΔEvq of the electron trapping well layer of the semiconductor light emitting device of the second example embodiment.

FIG. 8 shows a band structure near an active layer and a quantum well electron barrier layer of the semiconductor light emitting device of the second example embodiment.

FIG. 9A is a graph illustrating relationship between Al composition ratio in a 4 nm thick electron trapping well layer and calculated ΔEcq of an electron trapping well layer of the semiconductor light emitting devices of the third and fourth example embodiments. FIG. 9B shows a graph illustrating relationship between Al composition ratio in a 4 nm thick electron trapping well layer and calculated ΔEvq of the electron trapping well layer of the semiconductor light emitting devices of the third and fourth example embodiments.

FIG. 10A shows a graph illustrating relationship between Al composition ratio in a 2 nm thick electron trapping well layer and calculated ΔEcq of the electron trapping well layer of the semiconductor light emitting device of the fourth example embodiment. FIG. 10B shows a graph illustrating relationship between the Al composition ratio in the 2 nm thick electron trapping well layer and calculated ΔEvq of the electron trapping well layer of the semiconductor light emitting device of the fourth example embodiment.

FIG. 11A shows a graph illustrating relationship between Al composition ratio in a 6 nm thick electron trapping well layer and calculated ΔEcq of the electron trapping well layer of the semiconductor light emitting device of the fourth example embodiment. FIG. 11B is a graph illustrating relationship between the Al composition ratio in the 6 nm thick electron trapping well layer and calculated ΔEvq of the electron trapping well layer of the semiconductor light emitting device of the fourth example embodiment.

FIG. 12 is a cross-sectional view illustrating a first conventional semiconductor light emitting device.

FIG. 13 shows a band structure near an active layer of the first conventional semiconductor light emitting device.

FIG. 14 is a cross-sectional view illustrating a second conventional semiconductor light emitting device.

FIG. 15 shows a band structure near an active layer of the second conventional semiconductor light emitting device.

### DETAILED DESCRIPTION

### First Example Embodiment

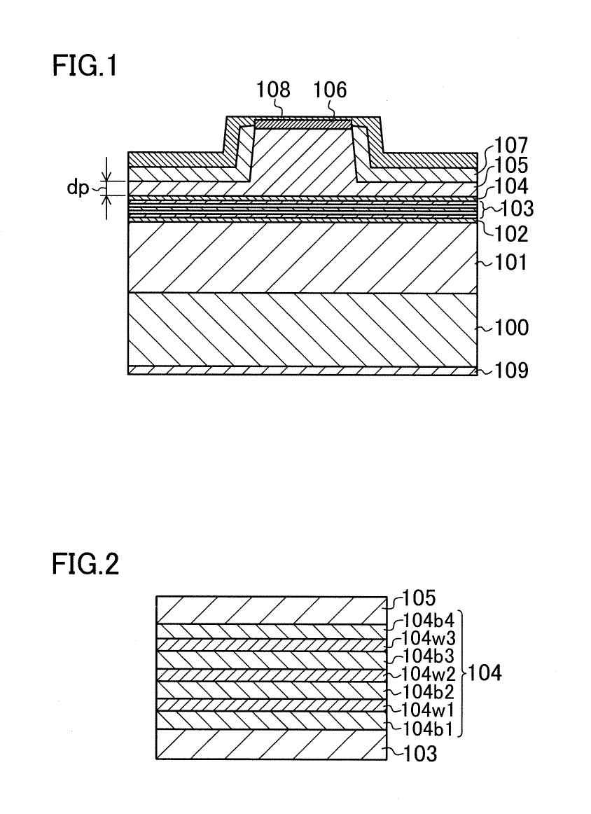

A semiconductor light emitting device of the first example embodiment will be described below with reference to FIG. 1.

As shown in FIG. 1, for example, a 2.5 μm thick first cladding layer 101 made of n-type aluminum gallium nitride (AlGaN), and a 86 nm thick guiding layer 102 made of n-type AlGaN are sequentially formed on a gallium nitride (GaN) semiconductor substrate 100. An active layer 103 which includes a multiple quantum well structure, and is made of indium gallium nitride (InGaN)-based material, for example, is formed on the guiding layer 102, and a p-type quantum well electron barrier layer 104 is formed on the active layer 103. A second cladding layer 105 which is made of p-type AlGaN, and has a ridge is formed on the quantum well electron barrier layer 104, and a 0.1 μm thick contact layer 106 made of p-type GaN is formed on a top surface of the ridge of the second cladding layer 105. A dielectric current block layer 107 which is made of SiN, and is transparent to light is formed on an upper surface and a side surface of the second cladding layer 105 except for the top surface of the ridge, and a p-side electrode 108 is formed to cover the contact layer 106 and the current block layer 107. An n-side electrode 109 is formed below the semiconductor substrate 100. A width of the ridge of the second cladding layer 105 is 1.4 μm. A distance from the top surface of the ridge to the active layer 103 is 0.5 μm, and a distance from a lower end of the ridge to the active layer 103 is 0.1 μm (dp).

In the first example embodiment, a composition ratio of aluminum (Al) in each of the first cladding layer 101 and the second cladding layer 105 is set to 0.05 to confine light in the vertical direction in the active layer 103. When the Al composition ratio in each of the first cladding layer 101 and the second cladding layer 105 is increased, a difference in refraction index between the active layer 103 and the first cladding layer 101, and between the active layer 103 and the second cladding layer 105 can be increased. Thus, the light can significantly be confined in the vertical direction in the active layer 103, thereby reducing a lasing threshold current. However, since there is a difference in thermal expansion coefficient between the first and second cladding layers 101 and 105, and the semiconductor substrate 100, excessive increase in Al composition ratio of the first and second cladding layers 101 and 105 leads to lattice defects, thereby reducing reliability. For this reason, the Al composition ratio in the first and second cladding layers 101 and 105 should be 0.2 or lower.

In the example structure, current injected from the contact layer 106 is narrowed by the current block layer 107 to flow to the ridge only, and the current is concentrated on the active layer 103 below the bottom of the ridge. Thus, population inversion of carriers, which is necessary for laser oscillation, can be achieved by injecting a current as low as several tens mA. The first cladding layer 101 and the second cladding layer 105 confine the light generated by recombination of the carriers injected in the active layer 103 in the vertical direction in the active layer 103. Further, the current block layer 107 confines the light in a direction parallel to the active layer 103 because the current block layer 107 has a lower refraction index than those of the first and second cladding layers 101 and 105. The current block layer 107 is transparent to laser oscillation light and does not absorb light, thereby providing a waveguide with low loss. Distribution of light propagating through the waveguide significantly expands toward the current block layer 107, and a difference in refraction index (Δn) in the order of 10⁻³ suitable for high power operation can easily be obtained. Further, the expansion can precisely be controlled by the distance between the current block layer 107 and the active layer 103 (dp). Thus, the distribution of light can precisely be controlled, and the semiconductor light emitting device can provide high power output at a low operating voltage.

When the semiconductor light emitting device is used as a light source for recording and reproducing of optical disc systems, the distribution of light has to have a unimodal, fundamental transverse mode oscillation to converge laser oscillation light to a diffraction limit on an optical disc.

To obtain stable fundamental transverse mode oscillation even in a high power and high temperature state, a higher order transverse mode oscillation has to be cut off, and a structure of the waveguide has to be determined to inhibit the higher order transverse mode oscillation.

Thus, Δn has to be controlled precisely in the order of 10⁻³, and the width of the bottom of the ridge has to be reduced to cut the higher order transverse mode oscillation off.

The width of the bottom of the ridge has to be 1.5 μm or smaller to reduce the higher order transverse mode oscillation. When the width of the bottom of the ridge is reduced, the width of the top surface of the ridge is also reduced since the ridge is in the form of a mesa. When the width of the top surface of the ridge is reduced too much, a path of the current injected from an upper portion of the ridge is narrowed. This may lead to increase in series resistance (Rs) of the semiconductor light emitting device, thereby increasing the operating voltage. Thus, when the width of the bottom of the ridge is reduced merely for the stable fundamental transverse mode oscillation, Rs is increased, and the operating voltage is increased. This may cause generation of heat, and the high power and high temperature operation becomes difficult.

Thus, in the first example embodiment, the width of the ridge is controlled to 1.4 μm so as not to increase Rs, and to have the fundamental transverse mode oscillation.

In the first example embodiment, the composition ratio of Al in the second cladding layer 105 is controlled to 0.05 to reduce cracking and lattice defects derived from the difference in thermal expansion coefficient between the second cladding layer 105 and the semiconductor substrate 100. In this case, a potential barrier ΔEc formed in a conduction band between the active layer 103 and the second cladding layer 105 is about 0.35 eV. Therefore, the electrons may leak to the second cladding layer 105 in the high power and high temperature operation when the second cladding layer 105 is merely formed on the active layer 103.

Thus, in the first example embodiment, the quantum well electron barrier layer 104 is provided between the active layer 103 and the second cladding layer 105. The quantum well electron barrier layer 104 will be described with reference to FIG. 2.

As shown in FIG. 2, the quantum well electron barrier layer 104 includes a first well layer 104w1, a second well layer 104w2, and a third well layer 104w3, which are p-type electron trapping well layers, and a first barrier layer 104b1, a second barrier layer 104b2, a third barrier layer 104b3, and a fourth barrier layer 104b4, which are p-type electron trapping barrier layers. Specifically, the first barrier layer 104b1, the first well layer 104w1, the second barrier layer 104b2, the second well layer 104w2, the third barrier layer 104b3, the third well layer 104w3, and the fourth barrier layer 104b4 are sequentially formed on the active layer 103. That is, each of the well layers is formed between the barrier layers. The quantum well electron barrier layer 104 of this embodiment includes the seven layers. However, the number of the layers is not limited to 7 as long as each of the well layers is sandwiched between the barrier layers. The electron trapping barrier layers are made of p-type AlGaN, for example, like the second cladding layer 105. The Al composition ratio in the electron trapping barrier layers is controlled to 0.3 to increase ΔEc. In this case, ΔEc is 0.71 eV, which is enough high to reduce the overflow of the electrons.

However, a band discontinuity of 0.35 eV (ΔEv) is formed in a valence band at an interface between the second cladding layer 105 and the fourth barrier layer 104b4, which provides a potential barrier to holes. The potential barrier increases a voltage at a rising edge of current-voltage characteristics, and increases Rs, thereby increasing the operating voltage. The nitride semiconductor light emitting device has a large band gap energy due to physical properties of the materials, and therefore, the operating voltage is inherently high. Thus, the reduction in operating voltage is of great importance.

In the first example embodiment, the band gap energies of the electron trapping well layers are determined in such a manner that the overflow of the electrons can be reduced, and the holes can pass through the quantum well electron barrier layer 104 by applying a bias voltage reduced as much as possible.

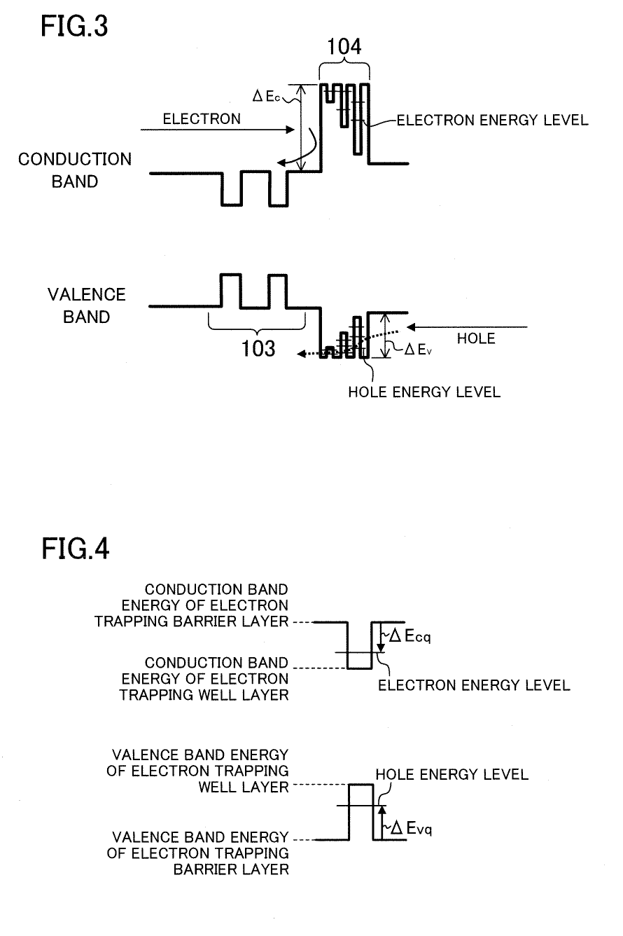

The band gap energy of the quantum well electron barrier layer 104 will be described with reference to FIG. 3.

As shown in FIG. 3, the band gap energies of the electron trapping well layers are determined in such a manner that the band gap energies decrease with decreasing distance from the second cladding layer 105.

The band gap energy of the first well layer 104w1 is close to the band gap energy of the first barrier layer 104b1. Thus, even when the electrons injected in the active layer 103 are excited by heat in the high power and high temperature operation, the electrons are less likely to reach the first well layer 104w1 by quantum tunneling because the first well layer 104w1 has high band gap energy. In particular, when the composition and the thickness of the first well layer 104w1 are determined in such a manner that a quantum energy level of the electrons is formed only at a ground level, and a second level is not formed in the first well layer 104w1, the electrons are much less likely to reach the first well layer 104w1 by quantum tunneling.

The band gap energy of the third well layer 104w3 is close to the band gap energy of the second cladding layer 105. Thus, two or more quantum energy levels of the holes are formed in the valence band of the third well layer 104w3. The holes injected from the second cladding layer 105 to the active layer 103 are more likely to tunnel through the fourth barrier layer 104b4 by quantum tunneling to be injected in the third well layer 104w3 even when the applied bias voltage is low. This can increase density of the holes in the third well layer 104w3, and the holes are more likely to tunnel through the third barrier layer 104b3 by quantum tunneling to reach the second well layer 104w2. This can increase the density of the holes in the second well layer 104w2.

The band gap energies of the electron trapping well layers increase with decreasing distance from the active layer 103. Accordingly, the magnitude of the hole energy levels formed at the ground level in the valence bands of the electron trapping well layers gradually increases, and the number of quantum energy levels gradually decreases, with decreasing distance from the active layer 103. As the holes travel through the electron trapping well layers toward the active layer 103, the holes in each of the valence bands of the electron trapping well layers are more likely to be at a quantum level having higher energy. In particular, when the band gap energy of the first well layer 104w1 is determined in such a manner that the hole energy level formed in the valence band of the first well layer 104w1 closest to the active layer 103 is within the range of 0.05 eV from a valence band edge of the first barrier layer 104b1, the operating voltage can effectively be reduced. In this case, the first well layer 104w 1 contains the holes having approximately the same energy as the valence band edge energy of the first barrier layer 104b1. As a result, thermal energy due to self heating of the operating semiconductor light emitting device allows the holes to pass through the first barrier layer 104b1. This eliminates the need to apply an extra bias voltage.

Thus, in the semiconductor light emitting device of the present embodiment, the holes can pass through the electron trapping barrier layers even when the applied bias voltage is low, and the increase in operating voltage can be reduced.

The structure of the quantum well electron barrier layer 104 will be described in detail below. When the Al composition ratio in the electron trapping barrier layers is 0.2 or higher, ΔEc in the conductive band between the electron trapping barrier layer and the active layer 103 is 0.5 eV or higher, thereby reducing the overflow of the electrons from the active layer 103. However, cracking or lattice defects may occur in the semiconductor light emitting device when the Al composition ratio is excessively increased. To prevent such disadvantages, the Al composition ratio in AlGaN electron trapping barrier layers should be 0.2 to 0.5, both inclusive, to reduce the overflow of the electrons, and to reduce the cracking and the lattice defects. However, when the Al composition ratio in the electron trapping barrier layers is increased, the electron trapping barrier layers function as a potential barrier to the holes injected from the second cladding layer 105, thereby increasing the operating voltage. In order to prevent the increase in operating voltage, the Al composition ratio in the electron trapping barrier layers should be 0.4 or lower. AlGaN layers having the Al composition ratio of 0.3 are used as the electron trapping barrier layers of the first example embodiment.

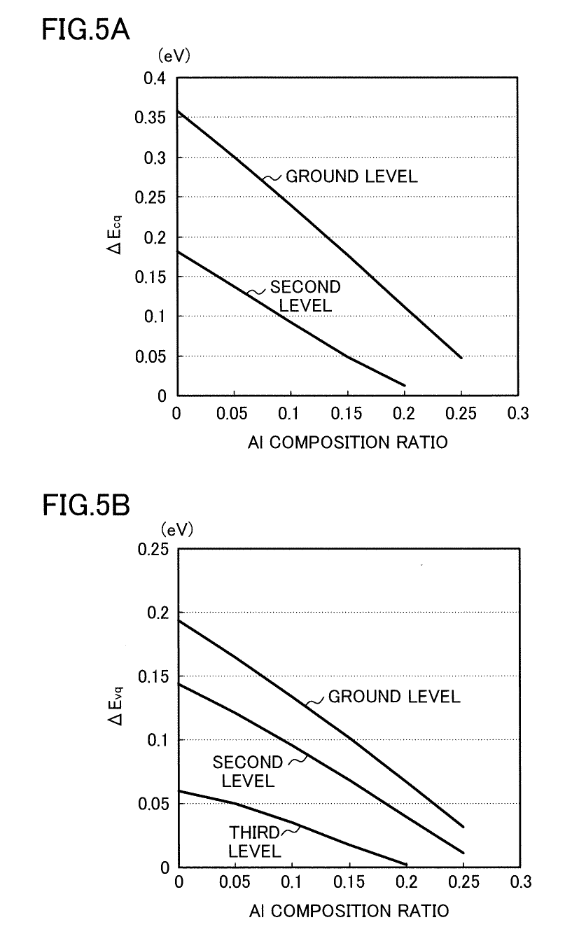

With the Al composition ratio in the AlGaN electron trapping barrier layers set to 0.3, and the thicknesses of the AlGaN electron trapping well layers set to 4 nm, the Al composition ratios in the electron trapping well layers will be described below with reference to FIGS. 4, 5A, and 5B.

In the following calculation of the energy level, as shown in FIG. 4, ΔEcq between a conduction band edge of the electron trapping barrier layer to an electron energy level formed in a conduction band of the electron trapping well layer, and ΔEvq between a valence band edge of the electron trapping barrier layer to a hole energy level formed in a valence band of the electron trapping well layer are calculated.

In the present embodiment, all the electron trapping well layers have the same thickness of 4 nm, and the Al composition ratios in the third well layer 104w3, the second well layer 104w2, and the first well layer 104w1 are 0.05, 0.15, and 0.25, respectively, i.e., increase with decreasing distance from the active layer 103. Then, as shown in FIG. 5B, the hole energy levels formed in the third well layer 104w3, the second well layer 104w2, and the first well layer 104w1, which are 0.17 eV, 0.11 eV and 0.035 eV when converted to ΔEvq, decrease with decreasing distance from the active layer 103 at a small pitch. As a result, the energy levels of the holes injected from the second cladding layer 105 to the active layer 103 efficiently increase with decreasing distance from the active layer 103, and the holes can reach the active layer 103 through the quantum well electron barrier layer 104. This can reduce the increase in operating voltage.

As shown in FIG. 5A, the electron energy level is formed only at the ground level in the first well layer 104w1 which is the closest to the active layer 103, and has the Al composition ratio of 0.25, and ΔEcq is as low as 0.05 eV. Therefore, the electrons are less likely to tunnel through the first barrier layer 104b1 closest to the active layer 103 by quantum tunneling to leak to the first well layer 104w1.

Thus, ΔEc formed at the interface between the first barrier layer 104b1 closest to the active layer 103, and the active layer 103 is less likely to decrease even when the electron trapping well layers are provided.

The semiconductor light emitting device of the first example embodiment can be driven at a low operating current and a low operating voltage even in the high power and high temperature operation.

### Second Example Embodiment

A semiconductor light emitting device of a second example embodiment will be described below. In the second example embodiment, the same components as those described in the first example embodiment will not be described in detail, and only the difference between the second and first example embodiments will be described below.

In the second example embodiment, AlGaN layers having the Al composition ratio of 0.3 are used as the electron trapping barrier layers. The third well layer 104w3, the second well layer 104w2, and the first well layer 104w1 are made of AlGaN having different Al composition ratios of 0.05, 0.15, and 0.25, respectively. Different from the first example embodiment, the first well layer 104w1, the second well layer 104w2, and the third well layer 104w3 have thicknesses of 2 nm, 4 nm, and 6 nm, respectively.

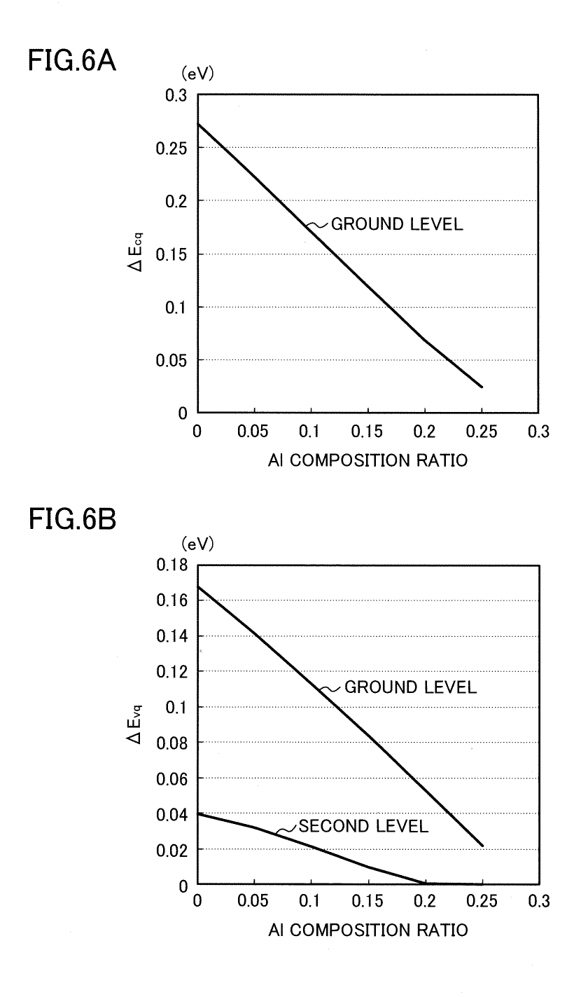

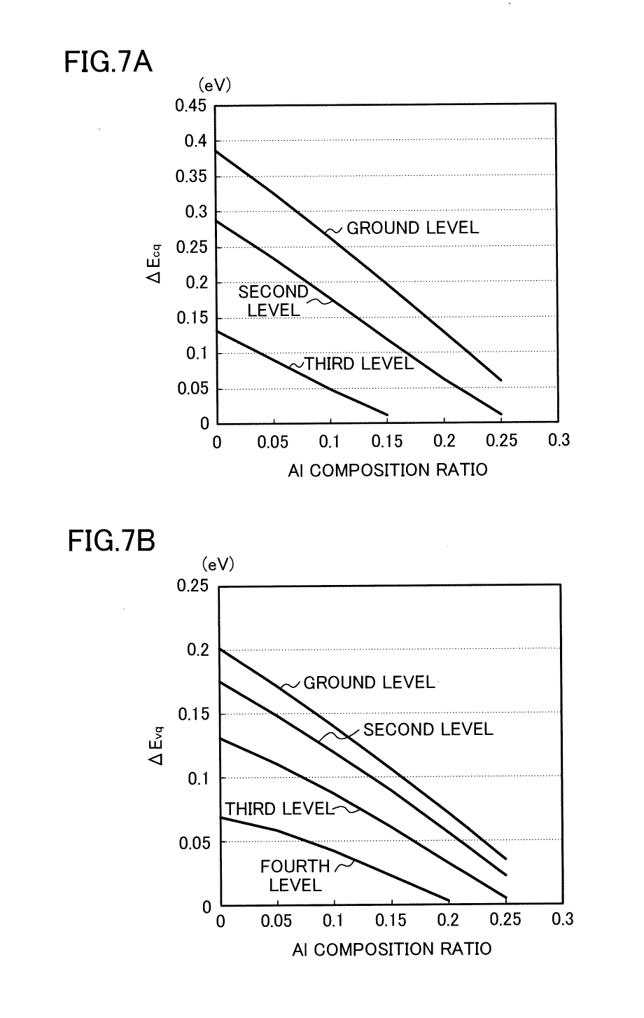

Quantum levels of electrons and holes formed in each of the electron trapping well layers of the second example embodiment will be described below with reference to FIGS. 5A to FIG. 8. FIGS. 5A and 5B show the quantum levels in the 4 nm thick second well layer 104w2, FIGS. 6A and 6B show the quantum levels in the 2 nm thick first well layer 104w1, and FIGS. 7A and 7B show the quantum levels in the 6 nm thick third well layer 104w3.

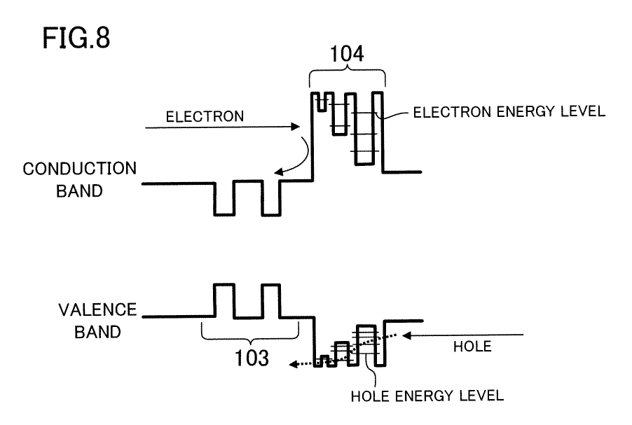

As shown in FIGS. 5B, 6B, and 7B, with the Al composition ratios and the thicknesses of the electron trapping well layers changed as described above, the hole energy levels at the ground level, which are 0.17 eV, 0.11 eV, and 0.025 eV when converted to ΔEvq, decrease with decreasing distance from the active layer 103 at a small pitch. Thus, the energy level of the holes injected from the second cladding layer 105 to the active layer 103 effectively increases with decreasing distance from the active layer 103, and the holes can reach the active layer 103 through the quantum well electron barrier layer 104. This can reduce the increase in operating voltage. In this case, the quantum well electron barrier layer 104 has a band structure shown in FIG. 8.

As shown in FIG. 6A, the electron energy level is formed only at the ground level in the first well layer 104w1, and the first well layer 104w1 is the thinnest well layer. Thus, ΔEcq is reduced to 0.025 eV, which is half the value of the first example embodiment (0.05 eV). In this case, the electrons are much less likely to tunnel through the first barrier layer 104b1 by quantum tunneling to leak to the first well layer 104w1.

Thus, ΔEc formed at the interface between the first barrier layer 104b1 and the active layer 103 is less likely to decrease even when the electron trapping well layers are provided.

The semiconductor light emitting device of the second example embodiment can be driven at a low operating current and a low operating voltage even in the high power and high temperature operation.

### Third Example Embodiment

A semiconductor light emitting device of a third example embodiment will be described below. In the third example embodiment, the same components as those of the first example embodiment will not be described in detail, and only the difference between the third and first example embodiments will be described below.

In the third example embodiment, AlGaN layers having the Al composition ratio of 0.3 are used as the electron trapping barrier layers, and 4 nm thick aluminum gallium indium nitride (AlGaInN) layers are used as the electron trapping well layers. The Al composition ratios of the third well layer 104w3, the second well layer 104w2, and the first well layer 104w1 are 0.05, 0.15, and 0.25, respectively.

The electron trapping barrier layers experience tensile strain due to the difference in lattice constant between the electron trapping barrier layers and the semiconductor substrate 100. When the Al composition ratio in the electron trapping barrier layers is increased to reduce the overflow of the electrons, the tensile strain increases, and lattice defects may occur near the active layer 103.

In the structure of the third example embodiment, compressive strain is induced in the electron trapping well layers to cancel the tensile strain of the electron trapping barrier layers.

Specifically, provided that the lattice constant of the electron trapping barrier layers is Lb, the lattice constant of the electron trapping well layers is Lw, and the lattice constant of GaN of the semiconductor substrate 100 is Lg, In composition ratios in the electron trapping well layers are determined to satisfy (Lb+Lw)/Lg=2. With the lattice constants determined in this way, the strain in the electron trapping barrier layers due to compressive lattice mismatch induced by the difference in lattice constant between the electron trapping barrier layers and the semiconductor substrate 100 can be canceled by inducing tensile lattice mismatch in the electron trapping well layers which is enough large to cancel the compressive strain in the electron trapping barrier layers. Further, when tensile lattice mismatch is induced in the electron trapping barrier layers, compressive lattice mismatch enough large to cancel the tensile strain of the electron trapping barrier layers may be induced in the electron trapping well layers.

In the third example embodiment, the third well layer 104w3, the second well layer 104w2, and the first well layer 104w1 have different Al composition ratios of 0.05, 0.15, and 0.25, respectively, and different In composition ratios of 0.071, 0.091, and 0.11, respectively.

With the compositions of the electron trapping well layers determined in this way, the strain in the quantum well electron barrier layer 104 due to the lattice mismatch can be canceled. Even when the electron trapping barrier layers having high Al composition ratio are used, the occurrence of lattice defects can be reduced. This can improve reliability of the semiconductor light emitting device in long-term operation.

The value (Lb+Lw)/Lg may not be exactly 2. As long as the value (Lb+Lw)/Lg satisfies 2-0.01≦(Lb+Lw)/Lg≦2+0.01, the lattice mismatch can be canceled, and the occurrence of lattice defects can be reduced.

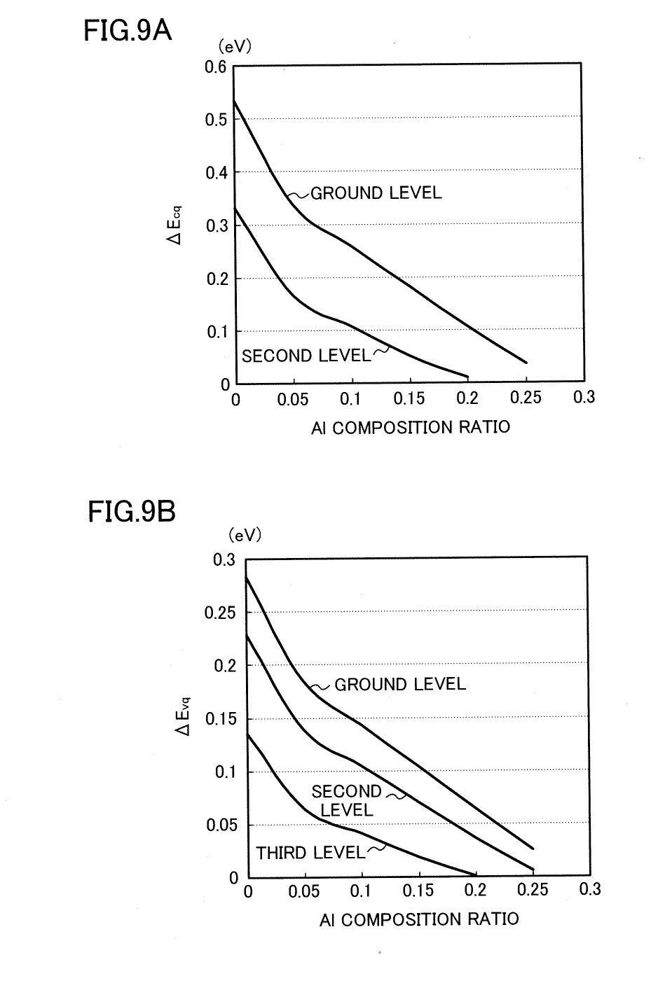

Quantum levels of holes and electrons formed in the electron trapping well layers of the third example embodiment will be described with reference to FIGS. 9A and 9B.

According to the calculation results shown in FIGS. 9A and 9B, the In composition ratios in the AlGaInN electron trapping well layers are varied to satisfy (Lb+Lw)/Lg=2.

As shown in FIG. 9B, the Al composition ratios in the third well layer 104w3, the second well layer 104w2, and the first well layer 104w1 are 0.05, 0.15, and 0.25, i.e., the Al composition ratios increase with decreasing distance from the active layer 103. Thus, the hole energy levels at the ground level, which are 0.18 eV, 0.11 eV, and 0.025 eV when converted to ΔEvq, decrease with decreasing distance from the active layer 103 at a small pitch. As a result, the energy levels of the holes injected from the second cladding layer 105 to the active layer 103 effectively increase with decreasing distance from the active layer 103, and the holes can reach the active layer 103 through the quantum well electron barrier layer 104. This can reduce the increase in operating voltage.

As shown in FIG. 9A, the electron energy level is formed only at the ground level in the first well layer 104w1, and ΔEcq is reduced to 0.04 eV. In this case, the electrons are much less likely to tunnel through the first barrier layer 104b1 by quantum tunneling to leak to the first well layer 104w1.

Thus, ΔEc formed at the interface between the first barrier layer 104b1 and the active layer 103 is less likely to decrease even when the electron trapping well layers are provided.

The semiconductor light emitting device of the third example embodiment can be driven at a low operating current and a low operating voltage even in the high power and high temperature operation, and the reliability of the semiconductor light emitting device in the long-term operation can be improved.

### Fourth Example Embodiment

A semiconductor light emitting device of a fourth example embodiment will be described below. In the fourth embodiment, the same components as those of the first and third example embodiments will not be described in detail, and only the difference between the fourth example embodiment and the first and third example embodiments will be described below.

In the fourth example embodiment, AlGaN layers having the Al composition ratio of 0.3 are used as the electron trapping barrier layers, and the thicknesses of the first well layer 104w1, the second well layer 104w2, and the third well layer 104w3 are 2 nm, 4 nm, and 6 nm, respectively. The Al composition ratios of the third well layer 104w3, the second well layer 104w2, and the first well layer 104w1 are 0.05, 0.15, and 0.25, respectively.

In the structure of the fourth example embodiment, like the third example embodiment, compressive strain is induced in the electron trapping well layers to cancel tensile strain in the electron trapping barrier layers.

The first well layer 104w1, the second well layer 104w2, and the third well layer 104w3 have different In composition ratios of 0.11, 0.091, and 0.071, respectively.

With the compositions of the electron trapping well layers determined in this way, the strain in the quantum well electron barrier layer 104 due to lattice mismatch can be canceled, and the occurrence of lattice defects can be reduced even when the electron trapping barrier layers having high Al composition ratio are used. This can improve reliability of the semiconductor light emitting device in the long-term operation.

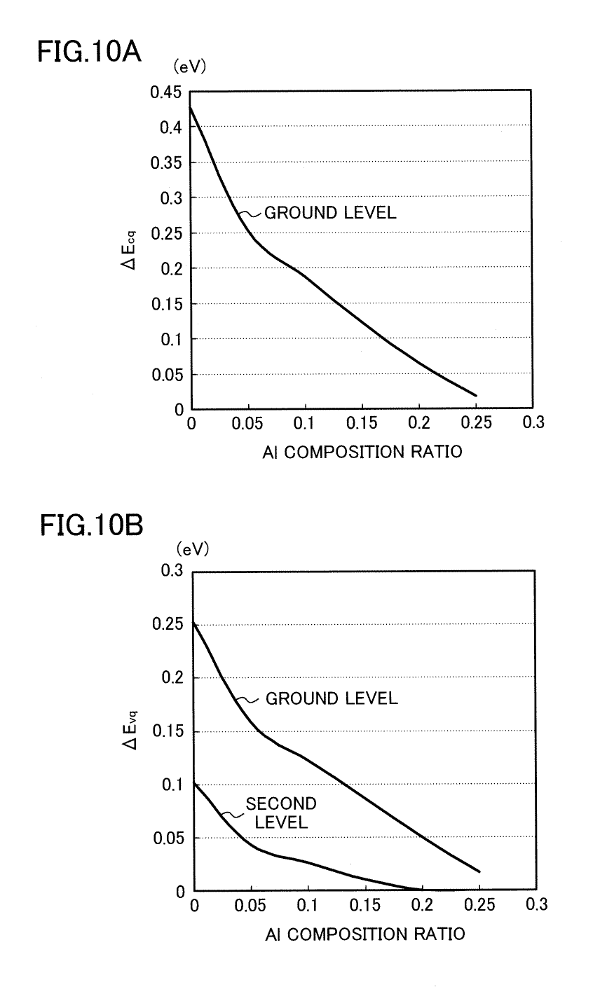

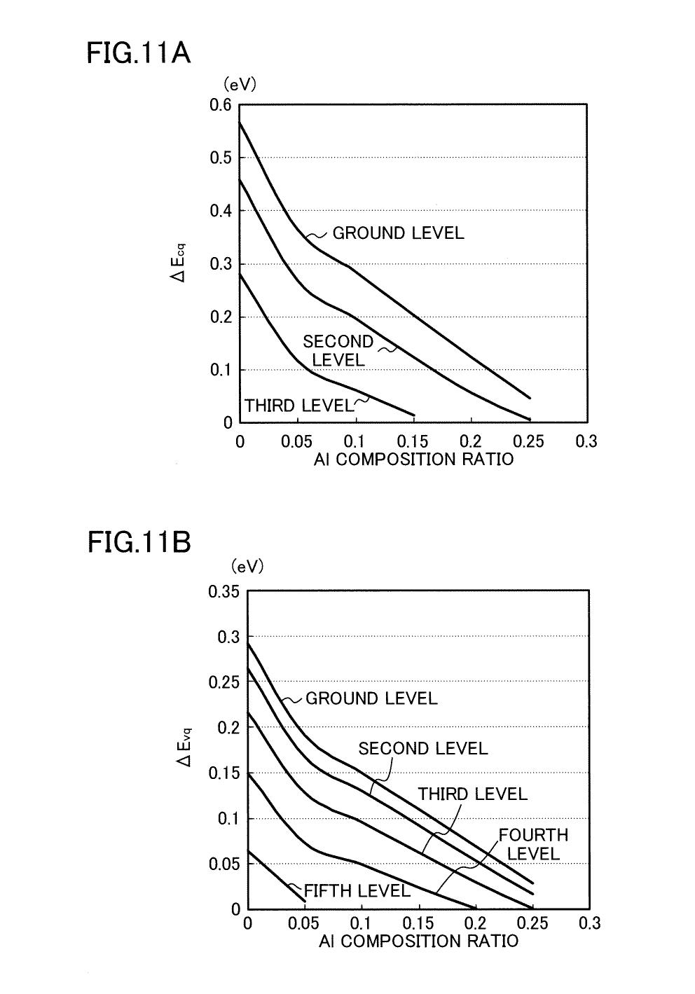

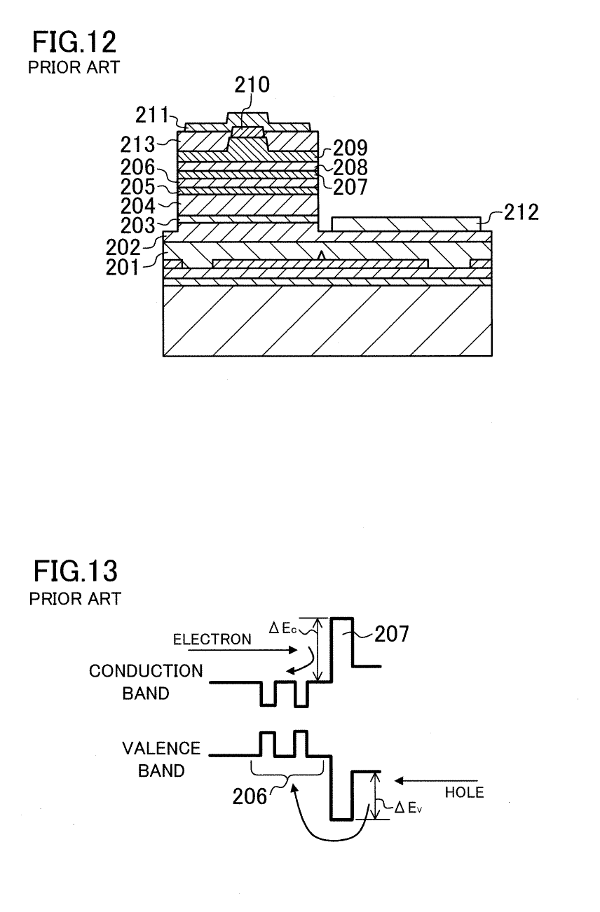

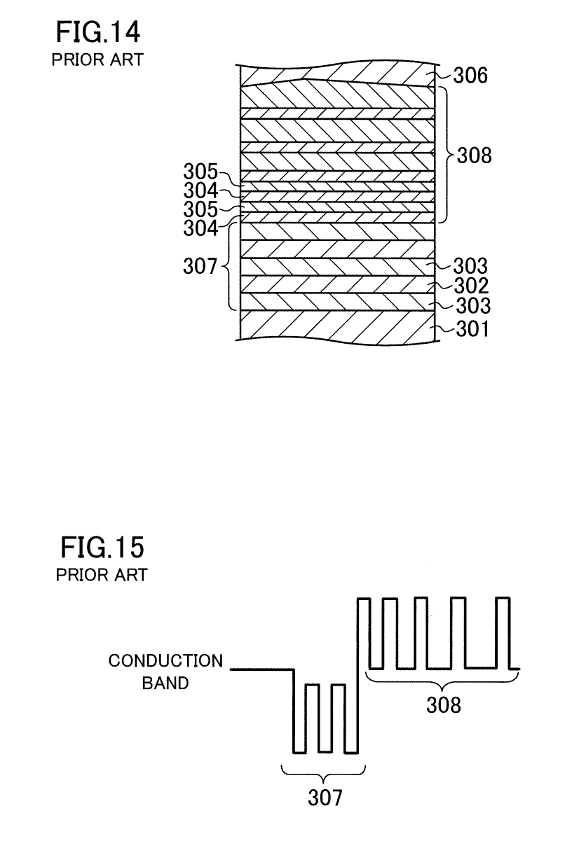

Quantum levels of electrons and holes formed in the electron trapping well layers of the fourth example embodiment will be described below with reference to FIGS. 9A to FIG. 11B. FIGS. 9A and 9B show the quantum levels in the 4 nm thick second well layer 104w2, FIGS. 10A and 10B show the quantum levels in the 2 nm thick first well layer 104w1, and FIGS. 11A and 11B show the quantum levels in the 6 nm thick third well layer 104w3.

As shown in FIGS. 9B, 10B, and 11B, with the Al composition ratios and the thicknesses of the electron trapping well layers changed as described above, the hole energy levels at the ground level, which are 0.2 eV, 0.11 eV, and 0.015 eV when converted to ΔEvq, decrease with decreasing distance from the active layer 103 at a small pitch. Thus, the energy levels of the holes injected from the second cladding layer 105 to the active layer 103 efficiently increase with decreasing distance from the active layer 103, and the holes can reach the active layer 103 through the quantum well electron barrier layer 104. This can reduce the increase in operating voltage.

As shown in FIGS. 9A, 10A, and 11A, the electron energy level is formed only at the ground level in the first well layer 104w1, and the first well layer 104w1 is the thinnest well layer. Thus, ΔEcq is reduced to 0.02 eV, which is less than half the value of the first example embodiment (0.05 eV). In this case, the electrons are much less likely to tunnel through the first barrier layer 104b1 by quantum tunneling to leak to the first well layer 104w1.

Thus, ΔEc formed at the interface between the first barrier layer 104b1 and the active layer 103 is less likely to decrease even when the electron trapping well layers are provided.

The semiconductor light emitting device of the fourth example embodiment can be driven at a low operating current and a low operating voltage even in the high power and high temperature operation, and the reliability of the semiconductor light emitting device in the long-term operation can be improved.

In the semiconductor light emitting devices of the first to fourth example embodiments, the Al composition ratio in the third well layer 104w3 is set to 0 to 0.05, both inclusive, thereby bringing the hole energy level formed at the ground level in the third well layer 104w3 close to the energy of the holes in the valence band of the second cladding layer 105. Thus, the holes are more likely to tunnel through the fourth barrier layer 104b4 by quantum tunneling, thereby reducing the operating voltage.

With the Al composition ratio in the electron trapping well layers set as high as, or higher than the Al composition ratio in the second cladding layer 105, the energy of the holes formed in the electron trapping well layers becomes as low as, or lower than the valence band edge energy of the second cladding layer 105. This can eliminate the need to apply an extra bias voltage for allowing the holes to tunnel through the quantum well electron barrier layer 104.

When the electron trapping well layers are thinned, the number of hole energy levels formed in the electron trapping well layers is reduced, and the holes are less likely to tunnel through the electron trapping barrier layers by quantum tunneling. When the electron trapping well layer and the electron trapping barrier layer form a mixed crystal at an interface therebetween, an average Al composition ratio in the electron trapping well layers increases, the number of quantum levels decreases, and the holes are less likely to tunnel through the barrier layers. When the electron trapping well layers are excessively thickened, the number of hole energy levels formed in the electron trapping well layers increases too much, and the holes are less likely to be at a high energy level, i.e., an energy level closest to the valence band edge energy of the electron trapping barrier layers. For these reasons, the thicknesses of the electron trapping well layers should be 2 nm to 6 nm, both inclusive.

In order to allow the holes to tunnel through the electron trapping barrier layers of the quantum well electron barrier layer 104 by quantum tunneling, the electron trapping barrier layers have to be as thick as, or thinner than a wavelength of a wave function of the holes, i.e., the thickness should be 8 nm or smaller. When the electron trapping barrier layers are thinned too much, the quantum levels of the electron trapping well layers are significantly bonded to form minibands. Thus, the quantum levels of the holes formed in the electron trapping well layers are split, and the holes are more likely to at low energy levels in the electron trapping well layers. When the holes travel from the electron trapping well layers to the active layer 103, the holes which are affected by a hetero barrier increases, and the operating voltage cannot be efficiently reduced. Thus, the thicknesses of the electron trapping barrier layers should be 2 nm to 8 nm, both inclusive, to allow the holes to efficiently tunnel through the barrier layers, and to prevent the formation of the minibands due to the bonding of the quantum levels of the electron trapping well layers. In the first to fourth example embodiments, the electron trapping barrier layers are 4 nm in thickness.

Thus, with the disclosed quantum well electron barrier layer 104 provided in the nitride semiconductor light emitting device, the holes can reach the active layer 103 from the second cladding layer 105 even when the applied bias voltage is low.

In the first to fourth example embodiments, only AlGaN has been described as the material of the electron trapping barrier layers, but AlGaN may be replaced with AlGaInN. In this case, the same advantages can be obtained when the electron trapping barrier layers are made of AlGaInN having band gap energies which are as large as, or larger than the band gap energy of the second cladding layer 105, and are larger than the band gap energies of the electron trapping well layers.

When the compositions of the electron trapping barrier layers are controlled in such a manner that the electron trapping barrier layers experience the tensile strain, the band gap energies of the electron trapping barrier layers increase. This can increase the quantum energy levels formed in the electron trapping well layers. As a result, the holes can pass through the potential barrier formed at the interface between the electron trapping barrier layer and the second cladding layer 105 even when the applied bias voltage is low, thereby reducing the operating voltage.

In the first to fourth example embodiments, the quantum well electron barrier layer 104 includes three electron trapping well layers. However, the number of the well layers is not limited to three. The holes can tunnel through the quantum well electron barrier layer 104 by quantum tunneling, and the operating voltage can be reduced as long as the thickness of the quantum well electron barrier layer 104 is 0.1 μm or smaller in total.

The present disclosure is not limited to the semiconductor lasers, and can advantageously be applied to semiconductor devices, such as light emitting diodes etc.

As described above, the disclosed semiconductor light emitting device can be driven at a low operating voltage and a low operating current even in the high power and high temperature operation, and is particularly useful for high power semiconductor light emitting devices etc.

What is claimed is:

1. A semiconductor light emitting device comprising:
a first cladding layer made of a first conductivity type group III nitride semiconductor;
an active layer formed on the first cladding layer;
a quantum well electron barrier layer which is formed on the active layer, and includes electron trapping barrier layers made of Al_{xb}Ga_{yb}In_{1-xb-yb}N (0≦xb<1, 0<yb≦1, 0≦1-xb-yb<1), and two or more electron trapping well layers made of Al_{xw}Ga_{yw}In_{1-xw-yw}N (0≦xw<1, 0<yw≦1, 0≦1-xw-yw<1); and
a second cladding layer which is formed on the quantum well electron barrier layer, and is made of a second conductive type group III nitride semiconductor, wherein
each of the electron trapping well layers is formed between the electron trapping barrier layers, and
band gap energies of the electron trapping well layers increase with decreasing distance from the active layer.

2. The semiconductor light emitting device of claim 1, wherein
xw representing a composition ratio of Al in the electron trapping well layer closest to the second cladding layer is 0 to 0.05, both inclusive.

3. The semiconductor light emitting device of claim 1, wherein
thicknesses of the electron trapping well layers are 2 nm to 6 nm, both inclusive, and
thicknesses of the electron trapping barrier layers are 2 nm to 8 nm, both inclusive.

4. The semiconductor light emitting device of claim 1, wherein
thicknesses of the electron trapping well layers decrease with decreasing distance from the active layer.

5. The semiconductor light emitting device of claim 1, wherein
the first cladding layer is formed on a semiconductor substrate.

6. The semiconductor light emitting device of claim 5, wherein
the semiconductor substrate is made of gallium nitride.

7. The semiconductor light emitting device of claim 1, wherein
xb representing a composition ratio of Al in the electron trapping barrier layer closest to the active layer is 0.2 or higher.

8. The semiconductor light emitting device of claim 5, wherein
a lattice constant of each of the electron trapping barrier layers is smaller than a lattice constant of the semiconductor substrate.

9. The semiconductor light emitting device of claim 6, wherein
2-0.01≦(Lb+Lw)/Lg≦2+0.01 is satisfied, where Lb is a lattice constant of the electron trapping barrier layer, Lw is a lattice constant of the electron trapping well layer, and Lg is a lattice constant of gallium nitride.
